(19) United States
(12) Patent Application Publication
(10) Pub. No.: US 2025/0169192 A1
(43) Pub. Date: May 22, 2025

(54) SEMICONDUCTOR DEVICE INCLUDING ELECTROSTATIC DISCHARGE (ESD) CIRCUIT

(71) Applicant: Samsung Electronics Co., Ltd., Suwon-si (KR)

(72) Inventors: Jongkyu Song, Suwon-si (KR); Jin Heo, Suwon-si (KR); Minho Kim, Suwon-si (KR); Jooyoung Song, Suwon-si (KR); Dongyup Lee, Suwon-si (KR); Chanhee Jeon, Suwon-si (KR)

(21) Appl. No.: 18/674,705

(22) Filed: May 24, 2024

(30) Foreign Application Priority Data
Nov. 22, 2023 (KR) 10-2023-0163581

(51) Int. Cl. H01L 27/02; H01L 29/73

(52) U.S. Cl. CPC H10D 89/711; H10D 10/00

(57) ABSTRACT

A semiconductor device includes a first pad configured to receive and transmit a signal; a second pad to which a predetermined reference voltage is input; and an electrostatic protection circuit includes an emitter region electrically connected to the second pad and doped with a first conductivity-type impurity, a base region having a shape surrounding the emitter region in the first direction and the second direction and doped with a second conductivity-type impurity, different from the first conductivity-type impurity, a collector region connected to the first pad and having a shape surrounding the emitter region in the first direction and the second direction, and an impurity region disposed between the collector region and the base region and separated from the collector region and the base region by an element isolation film.

### CROSS-REFERENCE TO RELATED APPLICATION(S)

This application claims benefit of priority to Korean Patent Application No. 10-2023-0163581 filed on Nov. 22, 2023 in the Korean Intellectual Property Office, the disclosure of which is incorporated herein by reference in its entirety.

### BACKGROUND

The present invention relates to a semiconductor device.

A semiconductor device may include a plurality of semiconductor circuits, and a portion of the plurality of semiconductor circuits may include a receiving circuit, a transmitting circuit, and the like, for exchanging a signal with a different external semiconductor device. The receiving circuit and the transmitting circuit may be connected to a pad for transmitting and receiving the signal. In order to protect semiconductor devices from electrostatic discharge (ESD) that may flow from the outside of the semiconductor device through the pad, the receiving circuit, the transmitting circuit, or the like may be connected to an ESD protection circuit. In order to effectively protect the semiconductor device, it is necessary to implement an ESD protection circuit that may include an element having a holding voltage, higher than an operating voltage of the receiving circuit and the transmitting circuit.

### SUMMARY

An aspect of the present inventive concept is to implement a semiconductor device having high ESD resistance using an ESD protection circuit having a holding voltage, higher than an operating voltage of a semiconductor circuit.

According to an aspect of the present inventive concept, a semiconductor device includes a first well region formed in a substrate and doped with a first conductivity-type impurity; a second well region formed in the substrate, doped with a second conductivity-type impurity, and disposed inside of the first well region in a first direction, parallel to an upper surface of the substrate; a collector region disposed in the first well region and doped with the first conductivity-type impurity; an impurity region disposed in the first well region and doped with the first conductivity-type impurity or the second conductivity-type impurity; an emitter region disposed in the second well region and doped with the first conductivity-type impurity; a base region disposed in the second well region, doped with the second conductivity-type impurity, and disposed between the collector region and the emitter region in the first direction; and a plurality of element isolation films disposed between the collector region, the emitter region, and the base region. At least one element isolation film, among the plurality of element isolation films, is disposed between the impurity region and the collector region.

According to an aspect of the present inventive concept, a semiconductor device includes a first pad configured to receive and transmit a signal; a second pad to which a predetermined reference voltage is input; and an electrostatic protection cell connected to the first pad and the second pad and including a plurality of unit elements arranged in a first direction and a second direction, parallel to an upper surface of a substrate. Each of the plurality of unit elements includes an emitter region electrically connected to the second pad and doped with a first conductivity-type impurity, a base region having a shape surrounding the emitter region in the first direction and the second direction and doped with a second conductivity-type impurity, different from the first conductivity-type impurity, a collector region connected to the first pad and having a shape surrounding the emitter region in the first direction and the second direction, and an impurity region disposed between the collector region and the base region and separated from the collector region and the base region by an element isolation film.

According to an aspect of the present inventive concept, a semiconductor device includes an NPN transistor including a collector region doped with an N-type impurity and connected to a first pad, a base region doped with a P-type impurity, and an emitter region doped with an N-type impurity and connected to a second pad; and a diode connected to the first pad, and including an N-type semiconductor region and a P-type semiconductor region. The collector region is disposed in a first well region doped with an N-type impurity, and the base region and the emitter region are disposed in a second well region doped with a P-type impurity and surrounded by the first well region. The N-type semiconductor region of the diode includes the first well region, and the P-type semiconductor region of the diode includes an impurity region disposed between the collector region and the base region and doped with a P-type impurity.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1 and 2 are views illustrating a semiconductor device according to an embodiment;

FIG. 3 is a circuit diagram illustrating an ESD protection circuit included in a semiconductor device according to an embodiment;

FIG. 4 is a graph illustrating an operation of the ESD protection circuit illustrated in FIG. 3 according to an embodiment;

FIG. 5 is a plan-view illustrating an NPN transistor included in the ESD protection circuit of FIG. 3 according to an embodiment;

FIGS. 6 and 7 are cross-sectional views illustrating an NPN transistor included in the ESD protection circuit of FIG. 3 according to example embodiments;

FIG. 8 is a circuit diagram illustrating an ESD protection circuit included in a semiconductor device according to an embodiment;

FIG. 9 is a cross-sectional view illustrating an NPN transistor included in the ESD protection circuit of FIG. 8 according to an embodiment;

FIG. 10 is a circuit diagram illustrating an ESD protection circuit included in a semiconductor device according to an embodiment;

FIG. 11 is a cross-sectional view illustrating an NPN transistor included in the ESD protection circuit of FIG. 10 according to an embodiment;

FIG. 12 is a circuit diagram illustrating an ESD protection circuit included in a semiconductor device according to an embodiment;

FIG. 13 is a cross-sectional view illustrating an NPN transistor included in the ESD protection circuit of FIG. 12 according to an embodiment;

FIG. 14 is a circuit diagram illustrating an ESD protection circuit included in a semiconductor device according to an embodiment;

FIGS. 15 to 18 are cross-sectional views illustrating an NPN transistor included in an ESD protection circuit according to example embodiments;

FIG. 19 is a plan-view illustrating an NPN transistor of an ESD protection circuit included in a semiconductor device according to an embodiment.

FIG. 20 is a cross-section view illustrating the ESD protection circuit of FIG. 19 according to an embodiment; and

FIG. 21 is a cross-sectional view illustrating an NPN transistor of an ESD protection circuit included in a semiconductor device according to an embodiment.

### DETAILED DESCRIPTION

Hereinafter, preferred embodiments will be described with reference to the attached drawings.

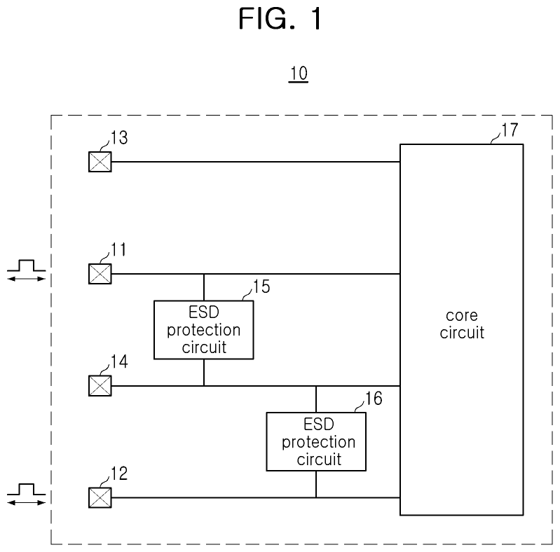

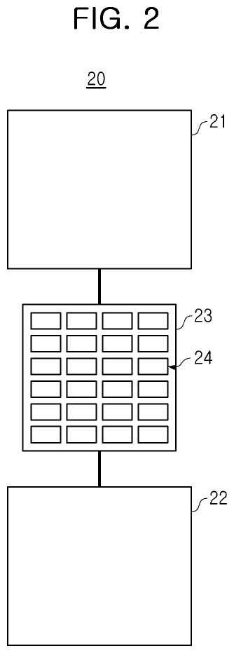

FIGS. 1 and 2 are views illustrating a semiconductor device according to an embodiment.

First, referring to FIG. 1, a semiconductor device 10 according to an embodiment may include signal pads 11 and 12, power pads 13 and 14, ESD protection circuits 15 and 16, a core circuit 17, and the like. The semiconductor device 10 may exchange a signal with a different external semiconductor device through the signal pads 11 and 12. For example, the core circuit 17 may include a transmitting circuit and a receiving circuit, connected to the signal pads 11 and 12.

The core circuit 17 may include a plurality of semiconductor elements. The semiconductor elements included in the core circuit 17 may include various circuits necessary for the semiconductor device 10 to provide given functions, such as a central processing unit (CPU), a graphic processing unit (GPU), an image signal processor (ISP), a neural processing unit (NPU), a modem, a cache memory, or the like.

A power supply voltage VDD and a reference voltage (or ground voltage) VSS, required for an operation of the core circuit 17 may be input to the power pads 13 and 14. For example, the power supply voltage VDD may be input to a first power pad 13, and the reference voltage VSS having a level, lower than a level of the power supply voltage VDD, may be input to a second power pad 14.

A high voltage due to static electricity or the like may be applied to at least a portion of the pads 11 to 14 of the semiconductor device 10. For example, under ESD event conditions in which a high voltage is applied to at least one of the signal pads 11 and 12 due to static electricity or the like, when a very large amount of ESD current generated due to ESD flows into the core circuit 17, the semiconductor elements may be damaged. In an embodiment, an ESD event may occur when a body is in close proximity to at least one of floated pads 11 to 14.

As above, to prevent damage to the semiconductor elements that may occur under the ESD event conditions, the ESD protection circuits 15 and 16 may be included in the semiconductor device 10. Each of the ESD protection circuits 15 and 16 may include an NPN transistor connected between one of the signal pads 11 and 12 and the second power pad 14. Additionally, each of the ESD protection circuits 15 and 16 may include a diode and/or a metal oxide semiconductor (MOS) transistor, or the like, connected to the NPN transistor.

The ESD protection circuits 15 and 16 may provide a path through which current flowing into the semiconductor device 10 flows under the ESD event conditions. When the ESD protection circuits 15 and 16 operate normally, current flowing into the signal pads 11 and 12 due to static electricity around the semiconductor device 10 may be drained to the second power pad 14 by the ESD protection circuit.

The ESD protection circuits 15 and 16 may have a trigger voltage and a holding voltage, determined according to characteristics of the NPN transistor, and when a voltage, higher than the trigger voltage, is applied, avalanche breakdown may occur such that the ESD current can be drained to the second power pad 14. Due to the avalanche breakdown, a voltage may be reduced to have the holding voltage, lower than the trigger voltage, and such that the ESD current can be drained to the second power pad 14.

When a difference between the holding voltage and the trigger voltage is large, the ESD protection function by the ESD protection circuits 15 and 16 may not be performed properly. For example, when a difference between the holding voltage and the trigger voltage is large and the holding voltage is smaller than an operating voltage of a semiconductor circuit (e.g., receiving circuit, transmitting circuit, etc.) included in the core circuit 17, a latch-up phenomenon in which the NPN transistors of the ESD protection circuits 15 and 16 continue to turn on may occur even after the ESD event has ended.

In an embodiment, the above latch-up phenomenon may be effectively prevented by implementing the ESD protection circuits 15 and 16 in which the difference between the trigger voltage and the holding voltage is not large. For example, in an embodiment, an additional impurity region between the collector region and the base region of the NPN transistor included in the ESD protection circuits 15 and 16 may be further formed to improve characteristics of the holding voltage of the NPN transistor, and to prevent the latch-up phenomenon of the ESD protection circuits 15 and 16.

FIG. 2 is a view illustrating a partial region of a semiconductor device 20 according to an embodiment. Referring to FIG. 2, a semiconductor device 20 according to an embodiment may include a first pad 21, a second pad 22, an electrostatic protection cell 23, and the like. The first pad 21 may be a pad through which a signal is input and/or output, and the second pad 22 may be a pad to which a predetermined reference voltage, for example, a ground voltage is input.

The electrostatic protection cell 23 may include a plurality of unit elements 24 arranged in a matrix form. Each of the plurality of unit elements 24 may include an NPN transistor, and the NPN transistor may be connected to at least one of an MOS transistor, a diode, or a resistor element, to provide an ESD protection circuit.

When an ESD event occurs to apply a high voltage to the first pad 21, and the voltage applied to the first pad 21 is higher than a trigger voltage of the ESD protection circuit, the NPN transistor may be turned on. Afterwards, as the voltage is reduced to have a holding voltage by the NPN transistor, an ESD current may flow into the second pad 22, and a large amount of current may be prevented from flowing into a core circuit.

When the holding voltage of the ESD protection circuit, which may be determined by characteristics of the NPN transistor, is not high enough, a latch-up phenomenon may occur as described above, affecting performance of the semiconductor device 20. Two or more electrostatic protection cells 23 between the first pad 21 and the second pad 22 may be connected to increase the holding voltage of the ESD protection circuit and alleviate the latch-up phenomenon, but, in this case, a degree of integration of the semiconductor device 20 may deteriorate. In an embodiment, an impurity region adjacent to a collector region of the NPN transistor may be added, to provide an ESD protection circuit having a sufficiently high holding voltage while minimizing an increase in an area of the electrostatic protection cell 23 connected between the first pad 21 and the second pad 22.

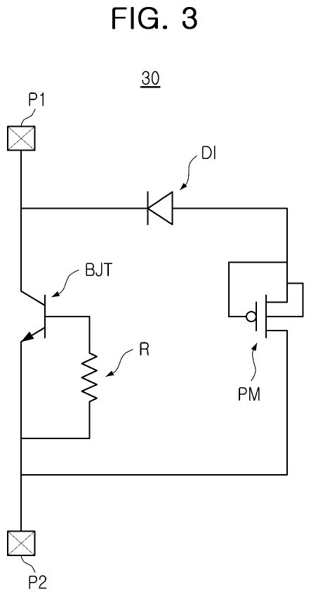

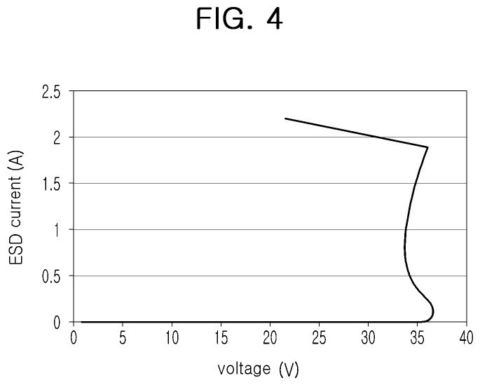

FIG. 3 is a circuit diagram illustrating an ESD protection circuit included in a semiconductor device according to an embodiment. FIG. 4 is a graph illustrating an operation of the ESD protection circuit illustrated in FIG. 3 according to an embodiment.

Referring to FIG. 3, an ESD protection circuit 30 according to an embodiment may include an NPN transistor BJT (bipolar junction transistor), a resistor element R, a diode DI, an MOS transistor PM, and the like. A collector of the NPN transistor BJT may be connected to a first pad P1 through which a signal is input and/or output, and an emitter of the NPN transistor BJT may be connected to a second pad P2 through which a predetermined reference voltage is input. The reference voltage input to the second pad P2 may be a ground voltage. Additionally, the emitter of the NPN transistor BJT may be connected to a base of the NPN transistor BJT through the resistor element R.

The collector of the NPN transistor BJT may be connected to a cathode of the diode DI, and the MOS transistor PM may be connected between an anode of the diode DI and the second pad P2. The MOS transistor PM may be a P-type MOS (PMOS) transistor, and may be a gate positive MOS (GPPMOS) transistor of which source and gate are connected to each other. As in other embodiments described later, at least one of the diode DI or the MOS transistor PM may not be included in the ESD protection circuit 30, and the MOS transistor PM may be also replaced with an N-type MOS (NMOS) transistor.

Hereinafter, an operation of the ESD protection circuit 30 illustrated in FIG. 3 will be described with reference to FIG. 4.

Referring to a graph in FIG. 4, an ESD current generated due to an ESD event is illustrated. The ESD current may flow when a voltage applied to the first pad P1 increases on or above a certain level due to the ESD event, and a voltage at which the ESD current rapidly increases may be defined as a trigger voltage.

When the ESD event occurs and the voltage of the first pad P1 increases on or above the trigger voltage, the NPN transistor BJT may be turned on, allowing the ESD current to flow to the second pad P2. As the ESD current flows, the voltage may decrease as illustrated in the graph illustrated in FIG. 4, and when the voltage decreases to a holding voltage, the ESD current may rapidly increase.

When a difference between the holding voltage and the trigger voltage of the ESD protection circuit 30 is large and the holding voltage is smaller than an operating voltage input in a normal operation, the NPN transistor BJT may continue to be turned on even after the ESD event ends. Therefore, since a current path may be formed between the first pad P1 and the second pad P2 by the ESD protection circuit 30, the semiconductor device including the ESD protection circuit 30 may not operate normally.

In an embodiment, the difference between the trigger voltage and the holding voltage in the ESD protection circuit 30 may be reduced by a design of the NPN transistor BJT. Therefore, the ESD protection circuit 30 having a sufficiently large amount of holding voltage may be implemented, and the ESD protection circuit 30 applicable to a semiconductor device in which a semiconductor circuit having a high operating voltage is included may be provided. For example, if the operating voltage is 30V the holding voltage may be higher than the operation voltage as shown in FIG. 4. Referring to FIG. 4, the ESD current may be about 0.2 A at the trigger voltage about 37V and may be about 1.9 A at the holding voltage about 36V.

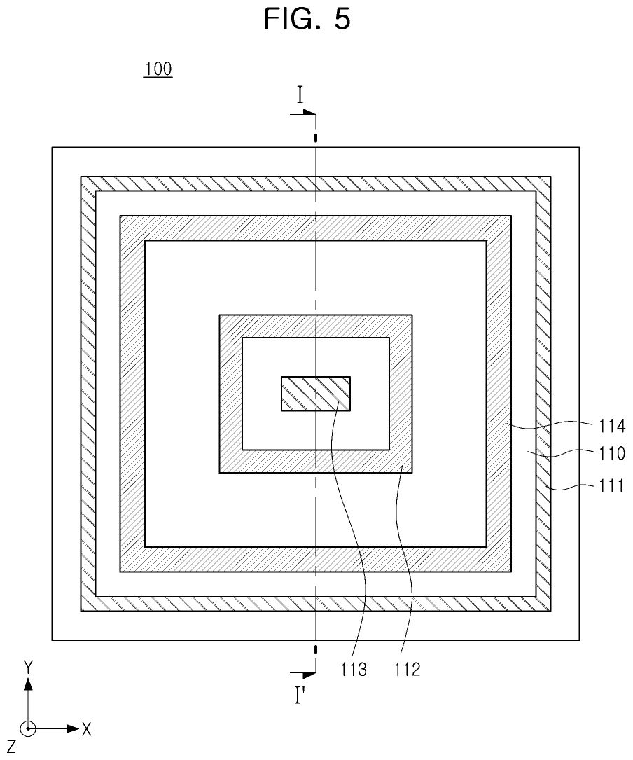

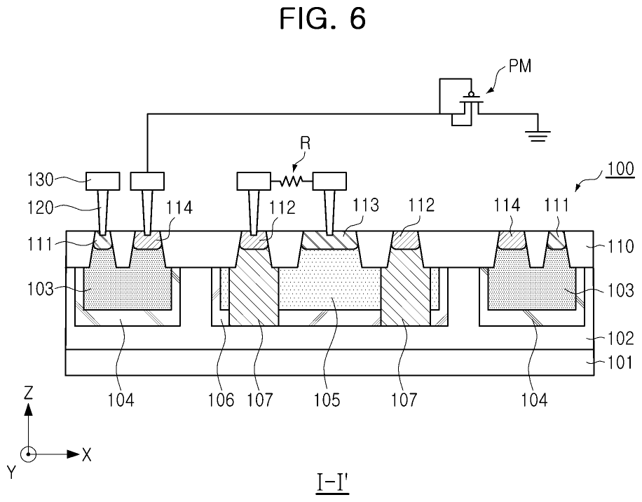

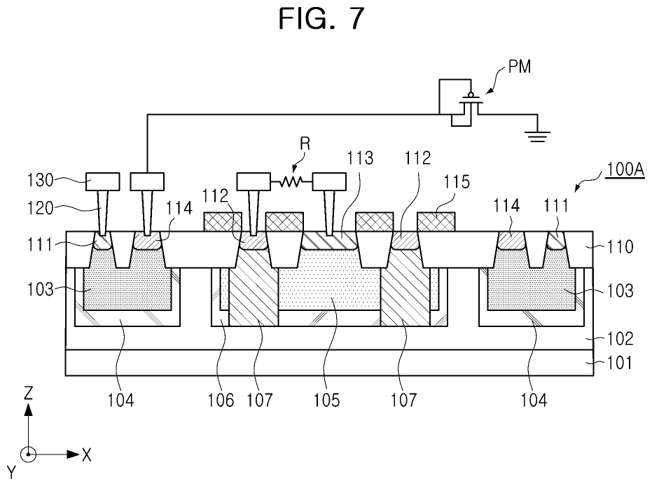

FIG. 5 is a plan-view illustrating an NPN transistor included in the ESD protection circuit of FIG. 3 according to an embodiment. FIGS. 6 and 7 are cross-sectional views illustrating an NPN transistor included in the ESD protection circuit of FIG. 3 according to example embodiments.

First, referring to FIG. 5, an NPN transistor 100 included in an ESD protection circuit of FIG. 3 according to an embodiment may include a collector region 111, a base region 112, and an emitter region 113. The collector region 111, the base region 112, and the emitter region 113 may be separated from each other by an element isolation film 110. For example, as illustrated in FIG. 5, the base region 112 may be disposed inside of the collector region 111, and the emitter region 113 may be disposed inside of the base region 112.

The collector region 111 and the emitter region 113 may be doped with a first conductivity-type impurity, respectively, and the base region 112 may be doped with a second conductivity-type impurity. For example, the collector region 111 and the emitter region 113 may be doped with an N-type impurity, and the base region 112 may be doped with a P-type impurity.

In an embodiment, an impurity region 114 may be disposed between the collector region 111 and the base region 112. In an embodiment described with reference to FIGS. 5 and 6, the impurity region 114 may be doped with the second conductivity-type impurity.

FIG. 6 is a cross-sectional view illustrating the NPN transistor of FIG. 5, taken along line I-I′. Referring to FIG. 6, an epitaxial layer 102 having a first conductivity-type may be formed on a substrate 101, and a first well region 103 and a second well region 105 may be formed in the epitaxial layer 102. An element isolation film 110 may be disposed between the first well region 103 and the second well region 105. As described with reference to FIG. 3, the collector region 111 may be connected to the first pad P1 through which a signal is input and/or output, and the emitter region 113 may be connected to the second pad P2 through which a reference voltage is input.

Depending on an embodiment, the first well region 103 and the second well region 105 may be formed in drift regions 104 and 106, respectively, such that an NPN transistor 100 may withstand a high voltage. A first drift region 104 may be doped with a first conductivity-type impurity, such as the first well region 103, and a second drift region 106 may be doped with a second conductivity-type impurity, such as the second well region 105.

A collector region 111 and an impurity region 114 may be formed in the first well region 103, and a base region 112 and an emitter region 113 may be formed in the second well region 105.

A diode may be provided by PN junction of the impurity region 114 and the first well region 103. For example, an N-type semiconductor region connected to a cathode of the diode may include the first well region 103, and a P-type semiconductor region connected to an anode of the diode may include the impurity region 114. It can be understood that the cathode of the diode is connected to the collector region 111, and the anode of the diode is connected to a PMOS transistor. For example, the MOS transistor PM has a source terminal and a gate terminal connected to each other and connected to the collector region 111 through the impurity region 114, and a drain terminal connected to the emitter region 113. In an embodiment illustrated in FIG. 6, a high voltage P-well region 107 may be formed below the base region 112.

The collector region 111, the base region 112, and the emitter region 113 may be connected to a wiring pattern 130 through a contact 120, respectively. Referring to FIG. 6, a resistance element R may be connected between wiring patterns 130 respectively connected to the base region 112 and the emitter region 113, and a wiring pattern 130 connected to the collector region 111 may be connected to a first pad through which a signal is input and/or output.

The impurity region 114 doped with a conductivity-type impurity, different from that of the collector region 111, may be formed in the first well region 103 in which the collector region 111 is formed. The impurity region 114 may be formed to reduce gain of the NPN transistor 100, and as a result, an effect of increasing a holding voltage may be obtained. Therefore, a holding voltage of an ESD protection circuit including the NPN transistor 100 may be set as being higher than an operating voltage of a core circuit connected to the ESD protection circuit, to suppress a latch-up phenomenon of the ESD protection circuit and effectively protect the core circuit.

The impurity region 114 doped with the second conductivity-type impurity may provide a diode together with the first well region 103. Therefore, the collector region 111 may be electrically connected to an MOS transistor PM through the diode provided by the impurity region 114 and the second well region 103. In this manner, by forming the impurity region 114 to implementing the diode connected to the collector region 111, it is possible to secure a discharge path to protect the core circuit from negative static electricity.

Referring to FIG. 7, an NPN transistor 100A according to an embodiment may further include a dummy gate structure 115 formed on at least a portion of an element isolation film 110. The dummy gate structure 115 may be formed of polysilicon, and may be electrically floated without being connected to a contact 120, a wiring pattern 130, or the like. The dummy gate structure 115 may be disposed, as illustrated in FIG. 7, to change breakdown voltage of the NPN transistor 100A. For example, the breakdown voltage of the NPN transistor 100A may be increased by the field effect of the dummy gate structure 115.

Referring to FIGS. 6 and 7, although not shown, collector regions 111 formed in first well regions 103 may be respectively electrically connected to each other through contacts 120 and wiring patterns 130, impurity regions 114 formed in the first well regions 103 may be respectively electrically connected to each other through contacts 120 and wiring patterns 130, and base regions 112 formed in high voltage P-well regions 107 may be respectively electrically connected to each other through contacts 120 and wiring patterns 130.

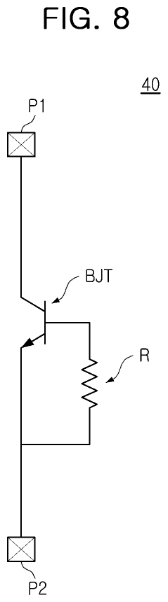

FIG. 8 is a circuit diagram illustrating an ESD protection circuit included in a semiconductor device according to an embodiment.

Referring to FIG. 8, an ESD protection circuit 40 according to an embodiment may include an NPN transistor BJT and the like. A collector of the NPN transistor BJT may be connected to a first pad P1 through which a signal is input and/or output, and an emitter of the NPN transistor BJT may be connected to a second pad P2 through which a predetermined reference voltage, for example, a ground voltage is input. The reference voltage input to the second pad P2 may be the ground voltage. Additionally, the emitter of the NPN transistor BJT may be connected to a base of the NPN transistor BJT through a resistor element R.

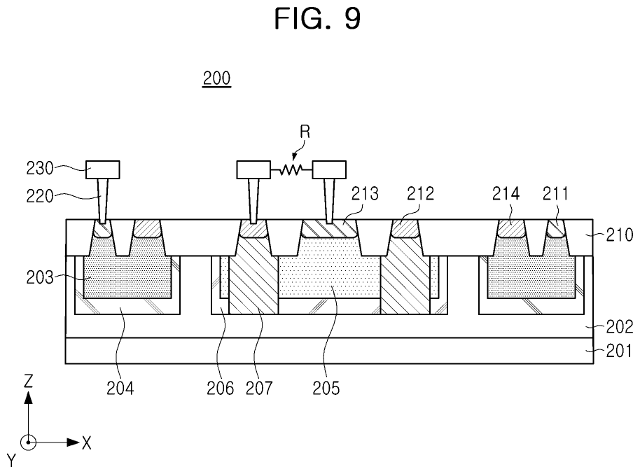

Unlike the embodiment previously described with reference to FIG. 3, in an embodiment illustrated in FIG. 8, a diode may not be connected to the collector of the NPN transistor BJT, and an MOS transistor may also not be connected thereto. This may be because an impurity region formed adjacent to a collector region in the NPN transistor BJT may be electrically floated. Hereinafter, it will be described in more detail with reference to FIG. 9.

FIG. 9 is a cross-sectional view illustrating an NPN transistor included in the ESD protection circuit of FIG. 8 according to an embodiment.

Referring to FIG. 9, an NPN transistor 200 included in an ESD protection circuit according to an embodiment may include a collector region 211, a base region 212, and an emitter region 213. The collector region 211 and the emitter region 213 may be doped with a first conductivity-type impurity, and the base region 212 may be doped with a second conductivity-type impurity. A first well region 203 in which the collector region 211 is formed, and a second well region 205 in which the base region 212 and the emitter region 213 are formed, may be separated from each other by an element isolation film 210. As described with reference to FIG. 8, the collector region 211 may be connected to the first pad P1 through which a signal is input and/or output, and the emitter region 213 may be connected to the second pad P2 through which a reference voltage is input.

The NPN transistor 200 according to an embodiment illustrated in FIG. 9 may have a structure similar to the NPN transistor 100 previously described with reference to FIGS. 5 and 6. For example, an epitaxial layer 202 having a first conductivity-type may be formed on a substrate 201, and the first well region 203 and the second well region 205 may be formed in the epitaxial layer 202. The first well region 203 may be formed in a first drift region 204, the second well region 205 may be formed in a second drift region 206, and a high voltage P-well region 207 may be formed below the base region 212.

The collector region 211, the base region 212, and the emitter region 213 may be connected to a wiring pattern 230 through a contact 220. The base region 212 and the emitter region 213 may be connected to each other by a resistance element R, and the wiring pattern 230 connected to the collector region 211 may be connected to the first pad P1 through which a signal is input and/or output.

An impurity region 214 formed in the first well region 203 together with the collector region 211 and doped with the second conductivity-type impurity, may not be connected to the contact 220 and the wiring pattern 230, but may be floated, as illustrated in FIG. 8. As explained with reference to the circuit diagram of FIG. 8, in an embodiment illustrated in FIG. 9, the NPN transistor 200 may not be connected to an MOS transistor.

As illustrated in FIG. 9, a dummy gate structure may be added to the NPN transistor 200 in which the impurity region 214 is floated. Similar to the embodiment previously described with reference to FIG. 7, the dummy gate structure may be formed on at least a portion of the element isolation film 210. In this manner, the dummy gate structure may be added to change breakdown voltage of the NPN transistor 200.

Referring to FIG. 9, although not shown, collector regions 211 formed in first well regions 203 may be respectively electrically connected to each other through contacts 220 and wiring patterns 230, and base regions 212 formed in high voltage P-well regions 207 may be respectively electrically connected to each other through contacts 220 and wiring patterns 230.

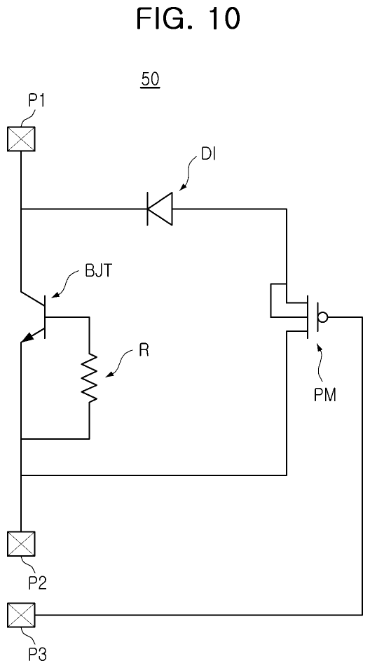

FIG. 10 is a circuit diagram illustrating an ESD protection circuit included in a semiconductor device according to an embodiment.

Referring to FIG. 10, an ESD protection circuit 50 according to an embodiment may include an NPN transistor BJT, a resistor element R, a diode DI, an MOS transistor PM, and the like. A collector of the NPN transistor BJT may be connected to a first pad P1 through which a signal is input and/or output, and an emitter of the NPN transistor BJT may be connected to a second pad P2 through which a predetermined reference voltage is input. The reference voltage input to the second pad P2 may be a ground voltage. Additionally, the emitter of the NPN transistor BJT may be connected to a base of the NPN transistor BJT through the resistor element R. The diode DI may be provided by PN junction of an N-well region and an impurity region formed adjacent to the collector of the NPN transistor BJT.

In an embodiment illustrated in FIG. 10, a gate of the MOS transistor PM may be connected to a third pad P3. The third pad P3 may be a pad to which a power supply voltage having a level, higher than a level of a reference voltage input to the second pad P2, is input.

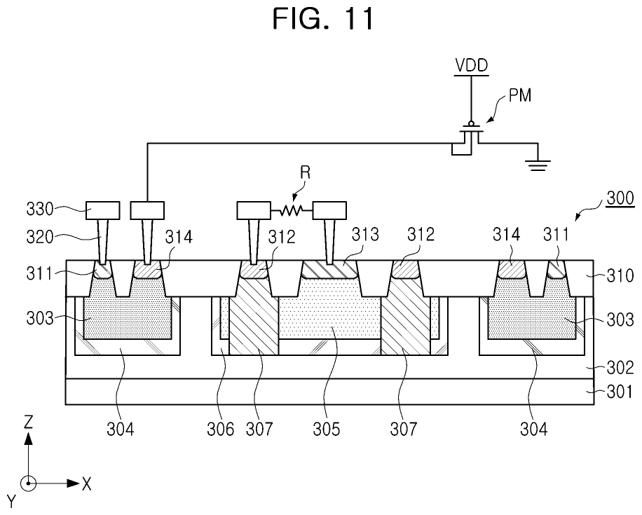

FIG. 11 is a cross-sectional view illustrating an NPN transistor included in the ESD protection circuit of FIG. 10 according to an embodiment.

In an embodiment illustrated in FIG. 11, an NPN transistor 300 may have a structure similar to the NPN transistor 100 previously described with reference to FIGS. 5 and 6. For example, an epitaxial layer 302 having a first conductivity-type may be formed on a substrate 301, and a first well region 303 and a second well region 305 may be formed in the epitaxial layer 302. The first well region 303 may be formed in a first drift region 304, the second well region 305 may be formed in a second drift region 306, and a high voltage P-well region 307 may be below a base region 312.

A collector region 311 and an impurity region 314 may be formed in the first well region 303. The collector region 311 may be doped with a first conductivity-type impurity, and the impurity region 314 may be doped with a second conductivity-type impurity. The base region 312 and an emitter region 313 may be formed in the second well region 305. The base region 312 may be doped with the second conductivity-type impurity, and the emitter region 313 may be doped with the first conductivity-type impurity. The first conductivity-type impurity may be an N-type impurity, and the second conductivity-type impurity may be a P-type impurity.

The collector region 311, the base region 312, the emitter region 313, and the impurity region 314 may be connected to a wiring pattern 330 through a contact 320, respectively. Wiring patterns 330 respectively connected to the base region 312 and the emitter region 313 may be connected to each other by a resistance element R, and a wiring pattern 330 connected to the emitter region 313 may be connected to a second pad P2 to which a reference voltage is input. A wiring pattern 330 connected to the collector region 311 may be connected to a first pad P1 through which signals is input and/or output, and a wiring pattern 330 connected to the impurity region 314 may be connected to an MOS transistor PM. The MOS transistor PM may be a P-type MOS (PMOS) transistor. Since a power supply voltage may be input to a gate of the MOS transistor PM, the MOS transistor PM may provide a gate powered PMOS (GPPMOS) transistor.

Referring to FIG. 11 although not shown, collector regions 311 formed in first well regions 303 may be respectively electrically connected to each other through contacts 320 and wiring patterns 330, impurity regions 314 formed in the first well regions 303 may be respectively electrically connected to each other through contacts 320 and wiring patterns 330, and base regions 312 formed in high voltage P-well regions 307 may be respectively electrically connected to each other through contacts 320 and wiring patterns 330.

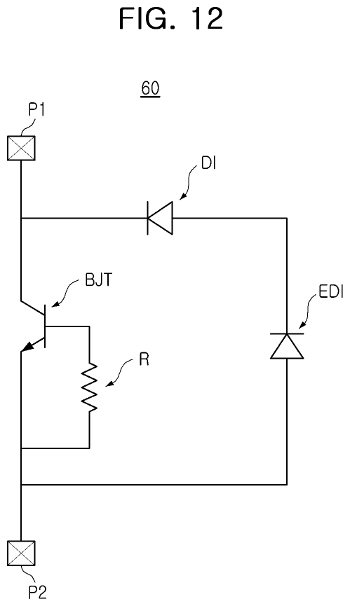

FIG. 12 is a circuit diagram illustrating an ESD protection circuit included in a semiconductor device according to an embodiment.

Referring to FIG. 12, an ESD protection circuit 60 according to an embodiment may include an NPN transistor BJT, a resistor element R, a diode DI, an external diode EDI, and the like. A collector of the NPN transistor BJT may be connected to a first pad P1 through which a signal is input and/or output, and an emitter of the NPN transistor BJT may be connected to a second pad P2 through which a predetermined reference voltage, for example, a ground voltage is input. Additionally, the emitter of the NPN transistor BJT may be connected to a base of the NPN transistor BJT through the resistor element R.

The diode DI may be provided by PN junction of an N-well region and an impurity region formed adjacent to a collector region of the NPN transistor BJT. A cathode of the diode DI may be electrically connected to the collector of the NPN transistor BJT and the first pad P1, and an anode of the diode DI may be electrically connected to the second pad P2 through the external diode EDI. Unlike the diode DI provided by the N-well region and the impurity region included in the NPN transistor BJT, the external diode EDI may be formed separately from the NPN transistor BJT.

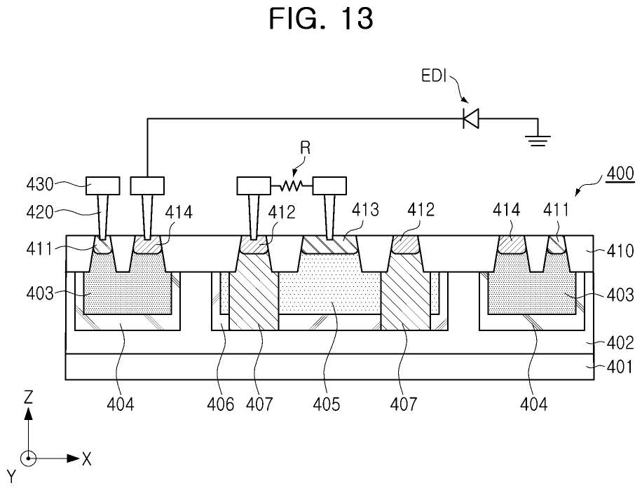

FIG. 13 is a cross-sectional view illustrating an NPN transistor included in the ESD protection circuit of FIG. 12 according to an embodiment.

Referring to FIG. 13, an NPN transistor 400 may have a structure similar to the NPN transistor 100 previously described with reference to FIGS. 5 and 6. For example, an epitaxial layer 402 having a first conductivity-type may be formed on a substrate 401, and a first well region 403 and a second well region 405 may be formed in the epitaxial layer 402. The first well region 403 may be formed in a first drift region 404, the second well region 405 may be formed in a second drift region 406, and a high voltage P-well region 407 may be formed in a corresponding region below a base region 412.

A collector region 411 and an impurity region 414 may be formed in the first well region 403. The collector region 411 may be doped with a first conductivity-type impurity, and the impurity region 414 may be doped with a second conductivity-type impurity. The base region 412 and an emitter region 413 may be formed in the second well region 405. The base region 412 may be doped with the second conductivity-type impurity, and the emitter region 413 may be doped with the first conductivity-type impurity. The first conductivity-type impurity may be an N-type impurity, and the second conductivity-type impurity may be a P-type impurity. The collector region 411, the base region 412, the emitter region 413, and the impurity region 414 may be connected to a wiring pattern 430 through a contact 420, respectively.

A diode may be provided by PN junction of the impurity region 414 and the first well region 403, and the impurity region 414 providing an anode of the diode may be connected to an external diode EDI through the wiring pattern 430. As illustrated in FIG. 13, the external diode EDI may be formed in a region, other than a region in which the NPN transistor 400 is formed.

Referring to FIG. 13 although not shown, collector regions 411 formed in first well regions 403 may be respectively electrically connected to each other through contacts 420 and wiring patterns 430, impurity regions 414 formed in the first well regions 403 may be respectively electrically connected to each other through contacts 420 and wiring patterns 430, and base regions 412 formed in high voltage P-well regions 407 may be respectively electrically connected to each other through contacts 420 and wiring patterns 430.

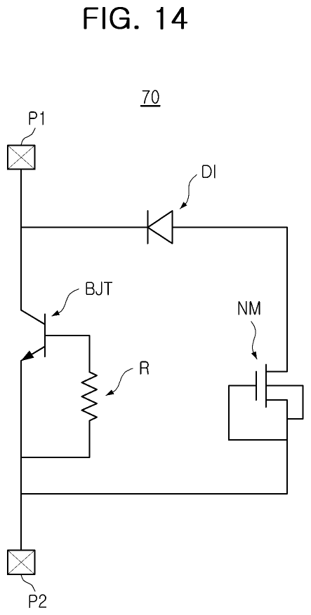

FIG. 14 is a circuit diagram illustrating an ESD protection circuit included in a semiconductor device according to an embodiment.

Referring to FIG. 14, an ESD protection circuit 70 according to an embodiment may include an NPN transistor BJT, a resistor element R, a diode DI, an MOS transistor NM, and the like. A collector and an emitter of the NPN transistor BJT may be connected to a first pad P1 and a second pad P2, respectively. As described above, the first pad P1 may be a pad through which a signal is input and/or output, and the second pad P2 may be a pad to which a predetermined reference voltage is input. The reference voltage input to the second pad P2 may be a ground voltage. Additionally, the emitter of the NPN transistor BJT may be connected to a base of the NPN transistor BJT through the resistor element R.

In an embodiment, the MOS transistor NM may be an NMOS transistor or a gate grounded NMOS (GGNMOS) transistor of which gate is connected to the pad P2.

For example, the NMOS transistor NM has a drain terminal and a gate terminal connected to each other and connected to the collector region 111 through the impurity region 114, and a drain connected to the emitter region 113.

The diode DI may be provided by PN junction of an N-well region and an impurity region formed adjacent to the collector of the NPN transistor BJT. A cathode of the diode DI may be electrically connected to the collector of the NPN transistor BJT and the first pad P1, and an anode of the diode DI may be electrically connected to the second pad P2 through the MOS transistor NM.

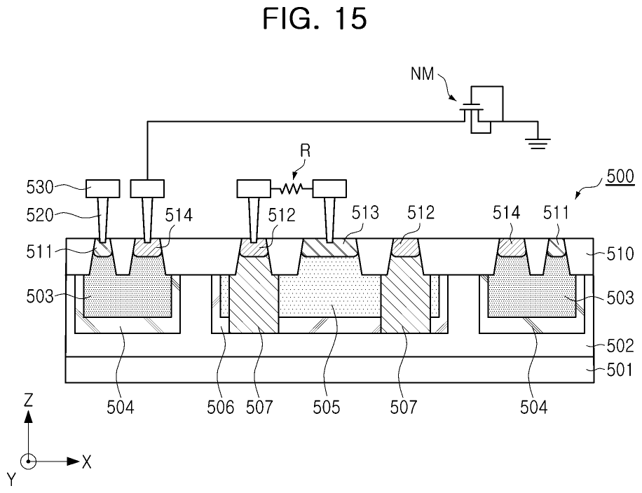

FIGS. 15 to 18 are cross-sectional views illustrating an NPN transistor included in an ESD protection circuit according to example embodiments.

FIG. 15 is a cross-sectional view illustrating an NPN transistor 500 included in the ESD protection circuit illustrated in FIG. 14. Referring to FIG. 15, an epitaxial layer 502 having a first conductivity-type may be formed on a substrate 501, and a first well region 503 and a second well region 505 may be formed in the epitaxial layer 502. The first well region 503 may be formed in a first drift region 504, and the second well region 505 may be formed in a second drift region 506. Depending on an embodiment, a high voltage P-well region 507 may be formed in a portion of the second drift region 506.

A collector region 511 doped with a first conductivity-type impurity and an impurity region 514 doped with a second conductivity-type impurity may be formed in the first well region 503. A base region 512 doped with the second conductivity-type impurity and an emitter region 513 doped with the first conductivity-type impurity may be formed in the second well region 505. The first conductivity-type impurity may be an N-type impurity, and the second conductivity-type impurity may be a P-type impurity. The collector region 511, the base region 512, the emitter region 513, and the impurity region 514 may be connected to a contact 520 and a wiring pattern 530.

A diode may be provided by PN junction of the impurity region 514 and the first well region 503, and the impurity region 514 providing an anode of the diode may be connected to the MOS transistor NM through the wiring pattern 530. For example, the MOS transistor NM has a drain terminal and a gate terminal connected to each other and connected to the collector region 511 through the impurity region 514, and a source terminal connected to the emitter region 513.

Referring to FIG. 15, although not shown, collector regions 511 formed in first well regions 503 may be respectively electrically connected to each other through contacts 520 and wiring patterns 530, impurity regions 514 formed in the first well regions 503 may be respectively electrically connected to each other through contacts 520 and wiring patterns 530, and base regions 512 formed in high voltage P-well regions 507 may be respectively electrically connected to each other through contacts 520 and wiring patterns 530.

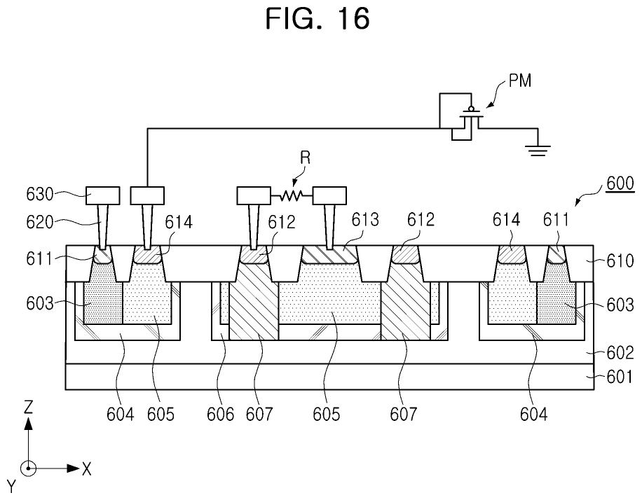

FIG. 16 is a cross-sectional view illustrating an NPN transistor of an ESD protection circuit included in a semiconductor device according to an embodiment.

Referring to FIG. 16, an NPN transistor 600 included in an ESD protection circuit may include an epitaxial layer 602 formed on a substrate 601, and a first well region 603, a second well region 605, a third well region 608, and the like, formed in the epitaxial layer 602. The first well region 603 and the third well region 608 may be formed in a first drift region 604, and the second well region 605 may be formed in a second drift region 606. Therefore, as illustrated in FIG. 16, the first well region 603 and the third well region 608 may be in contact with each other in the first drift region 604. A high voltage P-well region 607 may be formed in a portion of the second drift region 606. The first drift region 604 may be doped with a first conductivity-type impurity, such as the first well region 603, and the second drift region 606 may be doped with a second conductivity-type impurity, such as the second and third well regions 605 and 608.

A collector region 611 doped with a first conductivity-type impurity may be formed in the first well region 603. A base region 612 and an emitter region 613 may be formed in the second well region 605, and an impurity region 614 may be formed in the third well region 608. The first conductivity-type impurity may be an N-type impurity, and a second conductivity-type impurity may be a P-type impurity.

Therefore, in an embodiment illustrated in FIG. 16, a diode may be provided by PN junction by contact between the first well region 603 and the third well region 608. In terms of a circuit, a cathode of the diode may be electrically connected to the collector region 611, and an anode of the diode may be connected to an MOS transistor PM through a contact 620 and a wiring pattern 630.

Referring to FIG. 16, although not shown, collector regions 611 formed in first well regions 603 may be respectively electrically connected to each other through contacts 620 and wiring patterns 630, impurity regions 614 formed in third well regions 608 may be respectively electrically connected to each other through contacts 620 and wiring patterns 630, and base regions 612 formed in high voltage P-well regions 607 may be respectively electrically connected to each other through contacts 620 and wiring patterns 630.

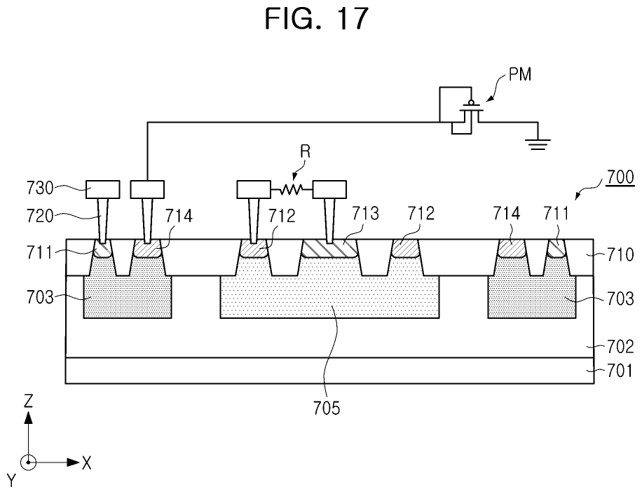

FIG. 17 is a cross-sectional view illustrating an NPN transistor of an ESD protection circuit included in a semiconductor device according to an embodiment.

Referring to FIG. 17, an NPN transistor 700 included in an ESD protection circuit may include an epitaxial layer 702 formed on a substrate 701, and a first well region 703, a second well region 705, and the like, formed in the epitaxial layer 702. Unlike other embodiments described above, in an embodiment illustrated in FIG. 17, a drift region may not be formed between the first well region 703, the second well region 705, and the epitaxial layer 702.

Structures may be similar to other embodiments described above, except that the drift region is not formed. For example, a collector region 711 and an impurity region 714 may be formed in the first well region 703, and a base region 712 and an emitter region 713 may be formed in the second well region 705. The collector region 711 and the emitter region 713 may be doped with an N-type impurity, respectively, and the base region 712 and the impurity region 714 may be doped with a P-type impurity, respectively. The impurity region 714 may provide a diode by PN junction with the first well region 703, and may be connected to an MOS transistor PM through a contact 720 and a wiring pattern 730.

Referring to FIG. 17, although not shown, collector regions 711 formed in first well regions 703 may be respectively electrically connected to each other through contacts 720 and wiring patterns 730, impurity regions 714 formed in the first well regions 703 may be respectively electrically connected to each other through contacts 720 and wiring patterns 730, and base regions 712 formed in the second well region 705 may be respectively electrically connected to each other through contacts 720 and wiring patterns 730.

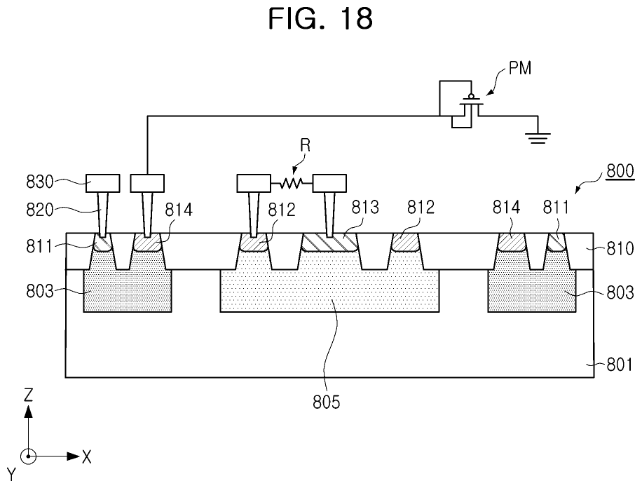

FIG. 18 is a cross-sectional view illustrating an NPN transistor of an ESD protection circuit included in a semiconductor device according to an embodiment.

Referring to FIG. 18, in an NPN transistor 800 included in an ESD protection circuit, a first well region 803 and a second well region 805 may be formed in a substrate 801 without an epitaxial layer and a drift region. The substrate 801 may have a second conductivity-type, unlike the epitaxial layer having the first conductivity-type included in the NPN transistor in other embodiments.

Structures may be similar to other embodiments described above, except that the epitaxial layer and the drift region are not formed. For example, a collector region 811 and an impurity region 814 may be formed in the first well region 803, and a base region 812 and an emitter region 813 may be formed in the second well region 805. The collector region 811 and the emitter region 813 may be doped with an N-type impurity, and the base region 812 and the impurity region 814 may be doped with a P-type impurity. The impurity region 814 may provide a diode by PN junction with the first well region 803, and may be connected to an MOS transistor PM through a contact 820 and a wiring pattern 830.

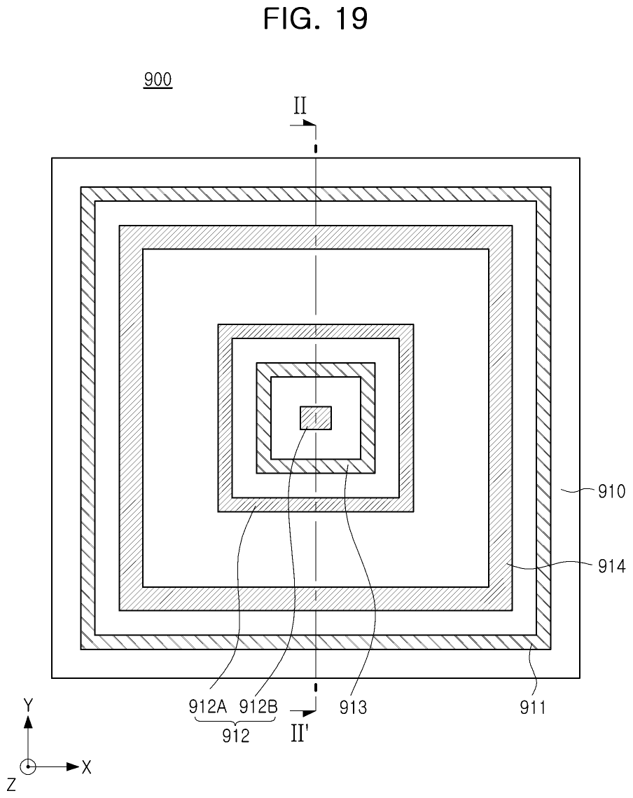

FIG. 19 is a plan-view illustrating an NPN transistor included in an ESD protection circuit according to an embodiment.

Referring to FIG. 19, an NPN transistor 900 included in an ESD protection circuit may include a collector region 911, a base region 912, and an emitter region 913. The collector region 911, base region 912, and emitter region 913 may be separated from each other by an element isolation film 910. The collector region 911 and the emitter region 913 may be doped with a first conductivity-type impurity, respectively, and the base region 912 may be doped with a second conductivity-type impurity. For example, the collector region 911 and the emitter region 913 may be doped with an N-type impurity, respectively, and the base region 912 may be doped with a P-type impurity.

Referring to FIG. 19, the base region 912 may include a first base region 912A surrounding an external side of the emitter region 913, and a second base region 912B disposed on an internal side of the emitter region 913.

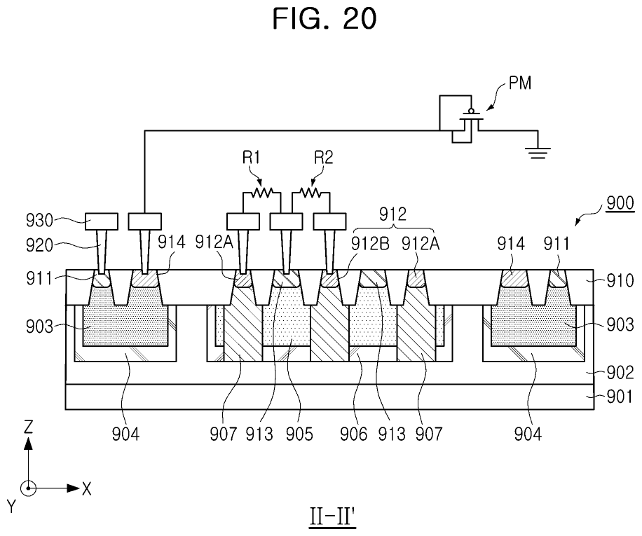

FIG. 20 is a cross-sectional view illustrating the NPN transistor 900 of FIG. 19, taken along line II-II′ direction, according to an embodiment.

Referring to FIG. 20, the first base region 912A may be connected to the emitter region 913 through a contact 920, a wiring pattern 930, and a first resistor element R1, and the second base region 912B may be connected to the emitter region 913 through the contact 920, the wiring pattern 930, and a second resistance element R2. Additionally, a high voltage P-well region 907 may be formed below the first base region 912A and the second base region 912B, respectively.

Other structures may be similar to other embodiments described above. A first well region 903 and a second well region 905 may be formed on an epitaxial layer 902 formed on a substrate 901, and may be surrounded by drift regions 904 and 906, respectively. An impurity region 914 may be connected to an MOS transistor PM through the contact 920 and the wiring pattern 930, and a diode may be implemented by the impurity region 914 and the first well region 903.

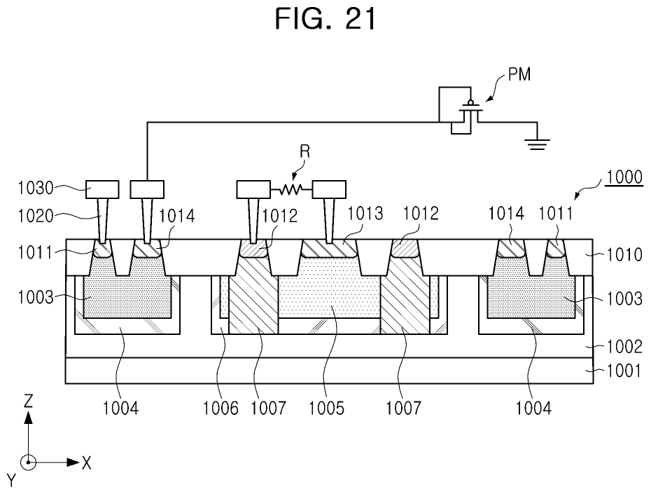

FIG. 21 is a cross-sectional view illustrating an NPN transistor of an ESD protection circuit according to an embodiment.

Referring to FIG. 21, an NPN transistor 1000 included in an ESD protection circuit may include an epitaxial layer 1002 formed on a substrate 1001, and a first well region 1003, a second well region 1005, and the like, formed in the epitaxial layer 1002. A first drift region 1004 may be formed between the first well region 1003 and the epitaxial layer 1002, and a second drift region 1006 may be formed between the second well region 1005 and the epitaxial layer 1002.

A collector region 1011 and an impurity region 1014 may be formed in the first well region 1003, and a base region 1012 and an emitter region 1013 may be formed in the second well region 1005. In an embodiment illustrated in FIG. 21, the collector region 1011, the emitter region 1013, and the impurity region 1014 may be doped with an N-type impurity, respectively, and the base region 712 may be doped with a P-type impurity. Since the impurity region 1014 may be doped with the N-type impurity, a diode may not be provided by the impurity region 1014. The impurity region 1014 may be connected to an MOS transistor PM through a contact 1020 and a wiring pattern 1030, but depending on an embodiment, the MOS transistor PM may not be connected to the impurity region 1014. In this case, the impurity region 1014 may be directly connected to a pad supplying a predetermined reference voltage, for example, a ground voltage.

Features of each of the above-described embodiments may be selectively cross-applied to each other. For example, a dummy gate structure 115, as described with reference to FIG. 7, may be included in each of the NPN transistors 200, 300, 400, 500, 600, 700, 800, 900, and 1000 according to the embodiments described with reference to FIGS. 9, 11, 13, 15, 16, 17, 18, 20, and 21. Also, in each of the NPN transistors 100, 100A, 200, 300, 400, 500, 700, 800, 900, and 1000 according to the embodiments described with reference to FIGS. 6, 7, 9,, 11, 13, 15, and 17 to 21, respectively, a well region doped with a P-type impurity, rather than an N-type impurity, may be formed below impurity regions 114, 214, 314, 414, 514, 714, 814, 914, and 1014, as described with reference to FIG. 16.

As in the embodiment illustrated in FIG. 20, a structure in which a base region 912 is divided into a first base region 912A and a second base region 912B, may be also applied to the NPN transistors 100, 100A, 200, 300, 400, 500, 600, 700, 800, and 1000 according to other embodiments. In addition, as in the embodiment illustrated in FIG. 11, a structure in which a power supply voltage VDD is input to a gate of an MOS transistor PM may be also applied to the MOS transistor PM connected to the NPN transistors 100, 100A, 600, 700, 800, 900, and 1000 according to other embodiments.

Various embodiments may overlap and be cross-applied. For example, as described with reference to FIG. 7, an element connected to an impurity region 114 of an NPN transistor 100A including a dummy gate structure 115 may be changed to an external diode, rather than an MOS transistor PM. In addition, a base region may be divided into a first base region 912A and a second base region 912B, as illustrated in FIG. 20. Alternatively, as illustrated in FIG. 21, in an NPN transistor 1000 in which an impurity region 1014 is doped with an N-type impurity, a dummy gate structure may be formed on at least a portion of an element isolation film 1010, and an MOS transistor PM may be replaced with an external diode, a power supply voltage VDD may be input to a gate of the MOS transistor PM, or the MOS transistor PM may be omitted and an impurity region 1014 may be electrically floated.

According to an embodiment, an impurity region may be further disposed between a collector region and a base region of an NPN transistor included in an ESD protection circuit to increase a holding voltage of the ESD protection circuit. Therefore, the holding voltage of the ESD protection circuit may be maintained to be higher than an operating voltage of a semiconductor device, to improve performance of the ESD protection circuit and effectively protect the semiconductor device.

Various advantages and effects of the present invention are not limited to the above-described content, and can be more easily understood through description of specific embodiments.

While example embodiments have been illustrated and described above, it will be apparent to those skilled in the art that modifications and variations could be made without departing from the scope of the present invention as defined by the appended claims.

What is claimed is:

1. A semiconductor device comprising:
a first well region formed in a substrate and doped with a first conductivity-type impurity;
a second well region formed in the substrate, doped with a second conductivity-type impurity, and disposed inside of the first well region in a first direction, parallel to an upper surface of the substrate;
a collector region disposed in the first well region and doped with the first conductivity-type impurity;
an impurity region disposed in the first well region and doped with the first conductivity-type impurity or the second conductivity-type impurity;
an emitter region disposed in the second well region and doped with the first conductivity-type impurity;
a base region disposed in the second well region, doped with the second conductivity-type impurity, and disposed between the collector region and the emitter region in the first direction; and
a plurality of element isolation films disposed between the collector region, the emitter region, and the base region,
wherein at least one element isolation film, among the plurality of element isolation films, is disposed between the impurity region and the collector region.

2. The semiconductor device of claim 1, further comprising:
a dummy gate structure disposed on the at least one element isolation film, among the plurality of element isolation films, and electrically floated.

3. The semiconductor device of claim 1, further comprising:
a resistance element connected between the base region and the emitter region.

4. The semiconductor device of claim 1, further comprising:
a metal oxide semiconductor (MOS) transistor having a source terminal connected to the collector region through the impurity region and a drain terminal connected to the emitter region.

5. The semiconductor device of claim 4, wherein the MOS transistor is a P-type MOS (PMOS) transistor including a gate terminal connected to the source terminal.

6. The semiconductor device of claim 4, wherein the MOS transistor is an N-type MOS (NMOS) transistor including a gate terminal connected to the emitter region.

7. The semiconductor device of claim 4, wherein the impurity region is connected to the source terminal of the MOS transistor.

8. The semiconductor device of claim 1, wherein the impurity region is electrically floated.

9. The semiconductor device of claim 1, further comprising:
a diode including an anode connected to the impurity region.

10. The semiconductor device of claim 9, wherein the diode includes a cathode connected to a pad to which a signal is input.

11. The semiconductor device of claim 1, wherein the base region includes:
a first base region disposed between the emitter region and the collector region in the first direction, and
a second base region disposed inside of the emitter region in the first direction.

12. A semiconductor device comprising:
a first pad configured to receive and transmit a signal;
a second pad to which a predetermined reference voltage is input; and
an electrostatic protection cell connected to the first pad and the second pad and including a plurality of unit elements arranged in a first direction and a second direction, parallel to an upper surface of a substrate,
wherein each of the plurality of unit elements includes:
an emitter region electrically connected to the second pad and doped with a first conductivity-type impurity,
a base region having a shape surrounding the emitter region in the first direction and the second direction and doped with a second conductivity-type impurity, different from the first conductivity-type impurity,
a collector region connected to the first pad and having a shape surrounding the emitter region in the first direction and the second direction, and
an impurity region disposed between the collector region and the base region and separated from the collector region and the base region by an element isolation film.

13. The semiconductor device of claim 12, wherein the collector region is doped with the first conductivity-type impurity, and
wherein the impurity region is doped with the second conductivity-type impurity.

14. The semiconductor device of claim 13, wherein the collector region is disposed in a well region doped with the first conductivity-type impurity, and
wherein the impurity region is disposed in a well region doped with the second conductivity-type impurity.

15. The semiconductor device of claim 12, wherein the collector region and the impurity region are doped with the first conductivity-type impurity, respectively.

16. The semiconductor device of claim 15, wherein each of the collector region and the impurity region is disposed in one well region doped with the first conductivity-type impurity.

17. A semiconductor device comprising:
an NPN transistor including a collector region doped with an N-type impurity and connected to a first pad, a base region doped with a P-type impurity, and an emitter region doped with an N-type impurity and connected to a second pad; and
a diode connected to the first pad, and including an N-type semiconductor region and a P-type semiconductor region,
wherein the collector region is disposed in a first well region doped with an N-type impurity, and the base region and the emitter region are disposed in a second well region doped with a P-type impurity and surrounded by the first well region,
wherein the N-type semiconductor region of the diode includes the first well region, and
wherein the P-type semiconductor region of the diode includes an impurity region disposed between the collector region and the base region and doped with a P-type impurity.

18. The semiconductor device of claim 17, wherein the impurity region is disposed in the first well region, together with the collector region.

19. The semiconductor device of claim 17, wherein the impurity region is disposed in a third well region contacting the first well region and doped with a P-type impurity.

20. The semiconductor device of claim 17, wherein the base region comprises a first base region disposed between the collector region and the emitter region, and a second base region disposed inside of the emitter region.
